(19) United States
(12) Patent Application Publication
(10) Pub. No.: US 2004/0058560 A1
(43) Pub. Date: Mar. 25, 2004

(54) Fast gas exchange for thermal conductivity modulation

(75) Inventors: Joseph Ranish, San Jose, CA (US); Dean Jennings, San Ramon, CA (US); Brian Haas, San Jose, CA (US)

Correspondence Address: PATENT COUNSEL, APPLIED MATERIALS, INC., Legal Affairs Department, P.O. BOX 450A, Santa Clara, CA, 95052, US

(73) Assignee: APPLIED MATERIALS, INC.

(21) Appl. No.: 10/251,485

(22) Filed: Sep. 20, 2002

(51) Int. Cl. H01L 21/26; H01L 21/324; H01L 21/477

(52) U.S. Cl. 438/795

(57) ABSTRACT

A method for thermally processing a semiconductor substrate comprises: heating the substrate to a target peak temperature while controlling the gas pressure in the processing chamber at a pressure level that is significantly lower than atmospheric pressure; providing a flow of a purge gas between the substrate and a thermal reservoir at or near the time the substrate temperature reaches the target peak temperature while adjusting the gas pressure in the processing chamber to a second pressure level. Preferably, the purge gas has a relatively high thermal conductivity.

The present application relates to semiconductor processing technologies, and particularly to a method of modulating thermal conductivity in a rapid thermal processing chamber.

### BACKGROUND OF THE INVENTION

One of the major processing steps in manufacturing computer chips from semiconductor substrates is thermal processing, which is used to produce uniform thin films and diffusion regions on the substrates. Thermal processing is traditionally dominated by batch furnace applications, but single wafer rapid thermal procesing (RTP) has become a mature and competitive technology. RTP uses short-time, high-temperature thermal treatments to minimize the effect of dopant diffusion caused by the thermal processing. In addition, RTP has several other advantages such as shorter cycle time, low thermal budget, reduced contamination, and high throughput. Its most common use is for annealing, which activates and controls the movement of atoms in the device after implantation. Another common use is for silicidation, which uses heat to form silicon-containing compounds with metals such as tungsten or titanium. RTP is also commonly used for gate dielectric formation, such as growing oxide on the wafer, and CVD glass reflow.

An RTP system typically includes an RTP chamber with heating and cooling elements. Substrates or wafers processed in RTP systems are thermally isolated from the heating elements, so that heating is performed primarily by thermal radiation. Various heating sources including tungsten halogen lamps, arc lamps and resistively heated susceptors are used as the heating elements. The RTP chamber provides a controlled environment and a means of coupling the thermal energy from the heating elements to the substrate being processed.

Thermal processing in an RTP system can last from a few seconds (e.g. spike anneal for source/drain formation) to a few minutes. As the industry moves to extremely short anneal times in advanced devices, the process of ramping up and cooling down account for a significant fraction of the total RTP time. The formation of ultra-shallow junctions, for example, requires precise, rapid (spike) implant anneals that limit high temperature exposure of the wafer to a few seconds. To enable these new device designs, precise temperature control, high temperature ramp rates, exceptional within-wafer uniformity, and wafer-to-wafer repeatability are required for the rapid thermal processes.

### SUMMARY OF THE INVENTION

The method of the present invention provides a rapid thermal process with enhanced temperature ramp rates and temperature uniformity across the substrate being processed. The rapid thermal process is performed in a processing chamber and comprises a heat-up phase and a cool-down phase. The enhanced temperature ramp rates are achieved by modulating thermal conduction from the substrate to a thermal reservoir through the use of different purge gases. The temperature ramp rates and temperature uniformity across the substrate are further enhanced by controlling the gas pressure in a thermal processing chamber. In one embodiment of the present invention, a flow of a first purge gas is introduced into a thermal processing chamber, while the gas pressure in the thermal processing chamber is maintained at a first pressure level. The first purge gas fills a reflective cavity between the substrate and the thermal reservoir and conducts heat between the substrate and the thermal reservoir while the temperature of the substrate is being ramped up. At or near the time when the substrate is at a predetermined peak temperature, a flow of a second purge gas is introduced into the processing chamber and the gas pressure in the processing chamber is adjusted to a second pressure level. The thermal conductivity of the first purge gas is lower than the thermal conductivity of the second purge gas. Both the first pressure level and the second pressure level are significantly lower than atmospheric pressure. Also, the first pressure level is preferred to be significantly lower than the second pressure level, so that the second purge gas quickly and uniformly fills the reflective cavity after the flow of the first purge gas is terminated and the flow of the second purge gas is started. The lower conductivity of the first purge gas limits heat transfer from the substrate to the thermal reservoir, allowing the substrate to be heated up quickly by a heating element. The higher conductivity of the second purge gas provides faster heat transfer from the substrate to the thermal reservoir when the substrate is being cooled down, resulting in higher substrate temperature ramp-down rate.

### BRIEF DESCRIPTION OF THE DRAWINGS

Additional objects and features of the invention will be more readily apparent from the following detailed description and appended claims when taken in conjunction with the drawings, in which:

FIG. 1A is a diagrammatic side view of a portion of an RTP system for processing a substrate according to one embodiment of the present invention;

FIG. 1B is a diagrammatic side view of a fluid injector which produces a substantially laminar flow of a purge gas across a surface of a portion of a reflector plate assembly;

FIG. 2 is a block diagram of a fluid control system that regulates gas flow rates and pressure in a processing chamber of the RTP system;

FIG. 3A is a graph illustrating a heating schedule during a rapid thermal process;

FIG. 3B is a flow diagram of a method for thermally processing a semiconductor substrate in the processing chamber;

FIGS. 4A and 4B are exploded views of the reflector plate assembly and the fluid injector shown in FIG. 1;

FIG. 4C is a diagrammatic top view of the reflector plate assembly and the fluid injector of FIG. 1 (features of the bottom reflector plate are shown using dashed lines);

FIG. 5 is a diagrammatic top view of an alternative fluid injector;

FIGS. 6A and 6B are diagrammatic side and top views of a portion of an alternative fluid injector, respectively;

FIGS. 7A and 7B are diagrammatic side and top views, respectively, of a portion of an alternative fluid injector;

FIGS. 8A and 8B are diagrammatic side and top views, respectively, of another fluid injector.

### DETAILED DESCRIPTION OF THE INVENTION

The method of the present invention can be performed in an RTP system capable of maintaining gas pressure in a processing chamber at a level that is significantly lower than the atmospheric pressure. An example of such an RTP system is the RADIANCE™ CENTURA® SYSTEM commercially available from Applied Materials, Inc., in Santa Clara, Calif.

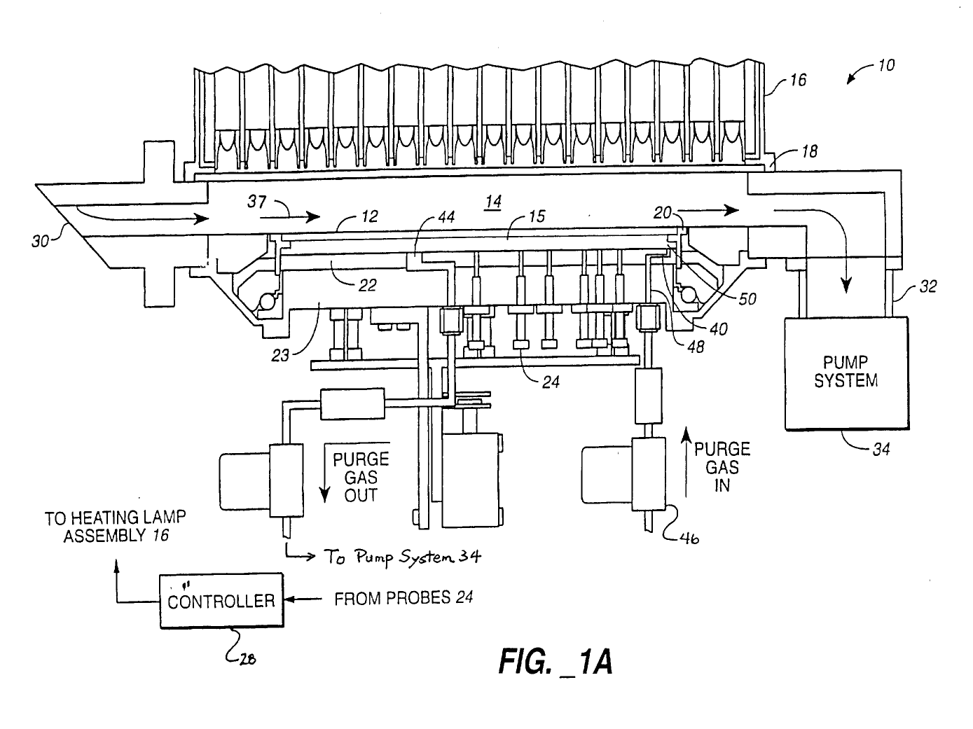

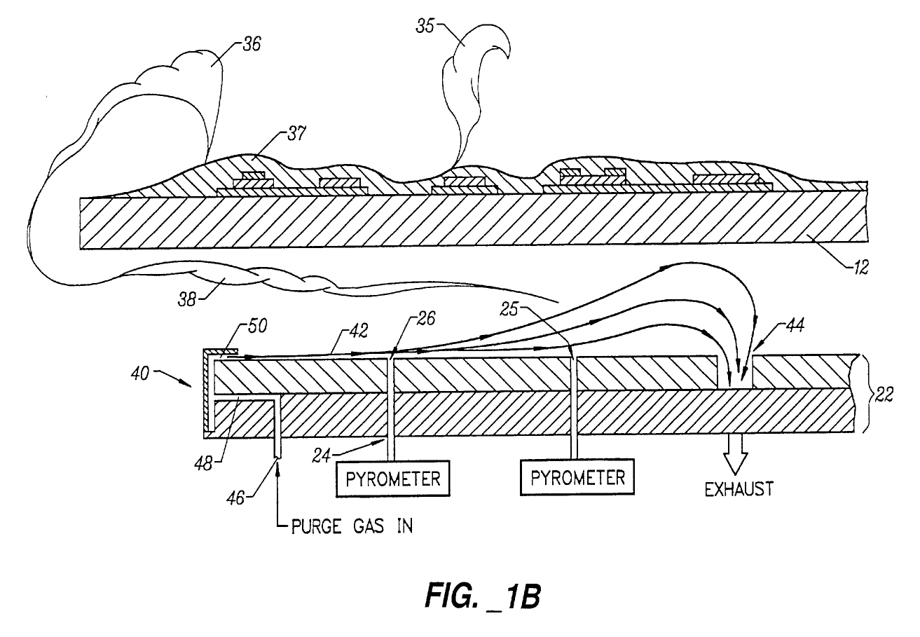

FIG. 1A illustrates an RTP system 10 including a processing chamber 14 for processing a disk-shaped semiconductor substrate 12, according to one embodiment of the present invention. Processing chamber 14 is radiatively heated through a water-cooled quartz window 18 by a heating element comprising a heating lamp assembly 16. The peripheral edge of substrate 12 is supported by a rotatable support structure 20, which can rotate at a rate of up to about 120 rpm (revolutions per minute). Beneath substrate 12 is a cooling element comprising a nickel-plated aluminum reflector plate assembly 22 that has an optically reflective surface facing the backside of substrate 12 to enhance the effective emissivity of substrate 12. Reflector plate assembly 22 is mounted on a water-cooled base 23, which is typically maintained at about room temperature, e.g., 23° C. Between the top surface of reflector plate assembly 22 and the backside of substrate 12 is a reflective cavity 15.

In a system designed for processing eight inch (200 mm) silicon wafers, reflector 22 has a diameter of about 8.9 inches, the separation between substrate 12 and the top surface of reflector 22 is about 5-10 mm, and the separation between substrate 12 and the bottom surface of quartz window assembly 18 is about 25 mm. In a system designed for processing twelve-inch (300 mm) silicon wafers, reflector 22 has a diameter of about 13 inches, the separation between substrate 12 and the top surface of reflector 22 is about 18 mm, and the separation between substrate 12 and the bottom surface of quartz window assembly 18 is about 30 mm.

The temperatures at localized regions of substrate 12 are measured by a plurality of temperature probes 24 that are positioned to measure substrate temperature at different radial locations across the substrate. Temperature probes 24 receive light from inside the processing chamber through optical ports 25, 26, and 27, which extend through the top surface of reflector plate assembly 22. While processing system 10 typically may have a total of ten temperature probes, only six probes are shown in FIG. 1. At the reflector plate surface, each optical port may have a diameter of about 0.08 inch. Sapphire light pipes deliver the light received by the optical ports to respective optical detectors (for example, pyrometers), which are used to determine the temperature at the localized regions of substrate 12. Temperature measurements from the optical detectors are received by a controller 28 that controls the radiative output of heating lamp assembly 16. The resulting feedback loop improves the ability of the processing system to uniformly heat substrate 12.

During processing, the top surface of substrate 12 is typically exposed to an ambient gas 37, which can be a process gas, a purge gas, or a combination of two or more gases. RTP processes for annealing are typically performed in inert ambient such as Ar or N₂. Oxidizing ambient with O₂ or BOₓ is used for Rapid Thermal Oxidation, while reactive species are used for RTCVD. Gases for the processing ambient are introduced into a processing region, which is the region on top of the substrate 12 in processing chamber 14, through ambient gas input 30. As shown in FIG. 1B, ambient gas 37 flows across the top surface of substitute 12. Excess ambient gas, as well as any reaction by-products 35, is withdrawn from processing chamber 14 through ambient gas output 32 by a pump system 34.

Most of the excess ambient gas and reaction products can be pumped out of processing chamber 14, but some volatile contaminants 36, especially those with relatively high vapor pressures such as BOₓ and POₓ, may leak into reflective cavity 15 and deposit onto the optical components situated around the reflective cavity. The rate at which volatile contaminants are deposited onto these optical components can be substantially reduced by a flow of a purge gas 42 across the top surface of reflective plate assembly 22. As described in commonly assigned U.S. Pat. No. 6,280,790 B1, which is incorporated herein by reference, a purge fluid injector 40 can be used to produce a substantially laminar flow of a purge gas across the top surface of reflector plate assembly 22.

As shown in FIG. 1B, purge gas 42 forms a contaminant-entraining bather between substrate 12 and the optical components. Volatile contaminants 36 are entrained in the purge gas flow 42, and removed through an exhaust port 44 or through ambient gas output 32 by pump system 34, rather than condense on the optically reflective surface of reflector plate assembly 22. In one embodiment of the present invention, when exhaust port 44 is provided for purge gas output, exhaust port 42 has a diameter of about 0.375 inch and is located about 2 inches from the central axis of reflector plate assembly 22. In operation, purge gas is injected into purge gas input 46 and is distributed through a plurality of channels 48 in reflector plate assembly 22. The purge gas is then directed against a deflector 50, which is spaced above the top surface of the reflector assembly by a distance, for example, of about 0.01 inch (0.25 mm), to produce the substantially laminar flow of purge gas 42.

The flow rates of the ambient gas and purge gas, and the gas pressure in processing chamber 14, are controlled by a fluid control system shown in FIG. 2. Mass flow controller (MFC) 80 is used to regulate the flow of ambient gas into processing chamber 14. Purge gas is introduced into processing chamber 14 through input 46 which is connected to a filter 86. A MFC 88 is used to regulate the flow of purge gas into processing chamber 14. An adjustable flow restrictor 90 and a mass flow meter (MFM) 92 are used to regulate the rate at which purge gas is removed from processing chamber 14. To reduce the migration of purge gas into the processing region of the processing chamber 14, which is above substrate 12, flow restrictor 90 is adjusted such that the rate at which purge gas is introduced into processing chamber 14 is substantially the same as the rate at which purge gas is removed from processing chamber 14. Solenoid shut-off valves 94 and 96 provide additional control over the flow of purge gas through processing chamber 14.

A closed-loop pressure control system is used to regulate the gas pressure in processing chamber 14 by controlling the rate at which gases are removed from processing chamber 14. In one embodiment of the present invention, the pressure control system comprises a pressure control valve 84 at ambient gas output 32, a pressure gauge 98 coupled to processing chamber 14, and a programmable logic controller (PLC) 82 coupled between pressure gauge 98 and pressure control valve 84. During the operation of the processing chamber 14, the pressure gauge 98 measures the pressure in processing chamber 14 periodically and sends the measured pressure value to PLC 82. The PLC 82 subtracts the measured pressure value from a pressure set point, which is the intended gas pressure in chamber 14, and uses an algorithm, such as proportional integral derivative (PID) control, to produce a control signal based on a set of tuning parameters. The control signal is sent to the pressure control valve 84, and the amount of flow through the valve 84 is adjusted accordingly.

In one embodiment of the present invention, processing chamber 14 is coupled to one or more transfer chambers (not shown), each through a load lock (not shown). The transfer chamber(s) and the associated load lock system facilitate transfers of substrates in and out of processing chamber 14 without substantially changing the gas pressure in processing chamber 14.

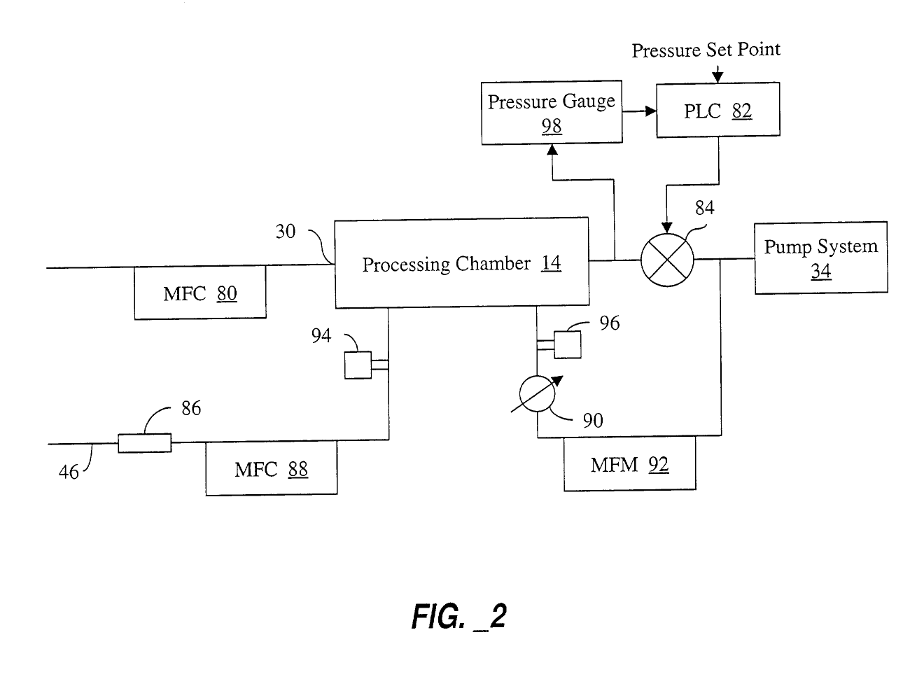

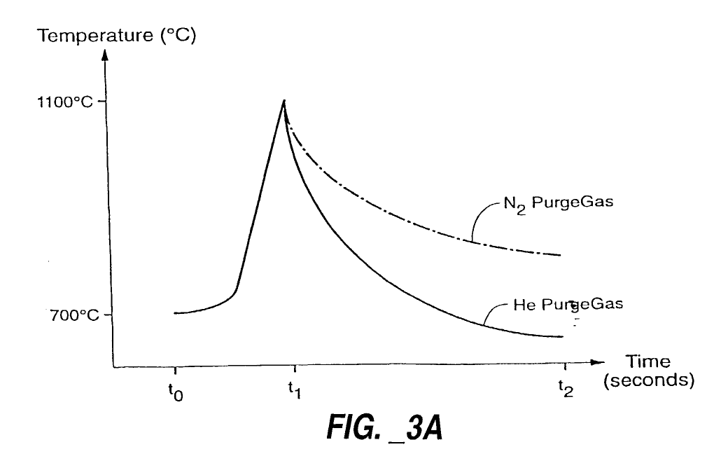

A substrate 12, after going through a dopant implant process, can be annealed in processing chamber 14 according to a heating schedule, such as the one shown in FIG. 3A. As illustrated in FIG. 3A, substrate 12 is heated to an initial temperature of about 700° C. by heating lamp assembly 16. At time to, heating lamp assembly 16 begins to heat the substrate to a target peak temperature (e.g. 1000° C. or 1100° C.). After the substrate has been heated to a temperature that substantially corresponds to the target peak temperature (at time t₁), the radiant energy supplied by heating lamp assembly 16 is reduced, and the substrate cools down until its temperature is below a threshold temperature (e.g. below 800° C.) and the substrate is removed from thermal processing chamber 14. Sometimes, when the substrate reaches the target peak temperature, the heating lamp assembly is adjusted to let the substrate soak near the peak temperature for a few seconds of soak time before it is turned off to allow the substrate to cool down.

As described in commonly assigned U.S. Pat. No. 6,215,206, which is incorporated herein by reference, the heat-up phase (e.g. between times t₀ and t₁ in FIG. 3A) or the cool-down phase (e.g. between times t₁ and t₂ in FIG. 3A), or both phases, may be optimized to improve the quality of the devices produced, by modulating the rate at which heat is transferred between a substrate and a thermal reservoir inside a processing chamber during the thermal process.

In one aspect, the rate at which the substrate is cooled may be substantially increased by proper selection of the purge gas supplied between substrate 12 and a thermal reservoir, e.g. water-cooled reflector plate assembly 22, inside processing system 10. In particular, a purge gas with relatively high thermal conductivity, e.g., helium, hydrogen, or a combination of these gases, provides better heat transfers between the substrate and the thermal reservoir, and therefore increases the cool-down rate of the substrate. The thermal conductivity of helium is about 5 times that of nitrogen. Thus, as illustrated in FIG. 3A, the rate at which the substrate cools is substantially greater when a purge gas such as helium with relatively high thermal conductivity is supplied into reflective cavity 15 than when a purge gas such as nitrogen with relatively low thermal conductivity is used. For certain devices (e.g. ultra-shallow junction transistors), a higher cool-down rate results in improved the operating characteristics or processing yield of the devices.

In another aspect, a purge gas, such as nitrogen, argon, krypton, xenon, or a combination these gases with a relatively low thermal conductivity may be supplied into reflective cavity 15 to limit heat transfer from the substrate to the thermal reservoir during the heat-up phase of the thermal process, so that the rate at which the substrate temperature increases is not significantly reduced by the purge gas. Using a low thermal conductivity purge gas during substrate heat-up is especially important in spike anneal processes, in which the substrate to reflector plate spacing is reduced in order to improve the ramp-down rate.

Thus, by proper selection of the purge gases supplied between the substrate and a thermal reservoir during the heat-up and cool-down phases of the thermal process, the overall thermal budget—i.e., ∫T(t)dt), the integral of substrate temperature T(t) over a fixed period of time, such as from time t₀ to t₂—may be reduced. This improves the quality of certain devices produced by such a thermal process.

In order to take full advantage of the different thermal conductivity values of the purge gases used in different phases of the thermal process, the higher thermal conductivity purge gas used in the cool down phase must quickly replace the lower thermal conductivity purge gas used in the heat-up phase. Fast gas exchange is especially important for spike anneal processes, where very short (<1 sec) or no soak time is used and cooling of the substrate starts right after the substrate reaches the target peak temperature. Fast exchange of different purge gases is achieved in the present invention by controlling the chamber pressure during the thermal process. FIG. 3B is a flow diagram of a process 300 for annealing semiconductor substrate 12 in processing chamber 14, according to one embodiment of the present invention. At step 310, substrate 12 is loaded onto support structure 20 in processing chamber 14. The gas pressure in processing chamber 14 is adjusted at step 320 by adjusting the pressure set point in the pressure control system to a first pressure value. In one embodiment of the present invention, the first pressure value is in the range of about 0.1-100 Torr, and more typically in the range of 1-20 Torr. In step 340, ambient gas 37 is supplied into the processing region in processing chamber 14. Also in step 340, if purging of the reflective cavity 15 is desired, a first purge gas may be supplied into reflective cavity 15 in processing chamber 14. The first purge gas is selected from a group of gases with relatively low thermal conductivity, such as nitrogen, argon, krypton, xenon, or a combination of these gases. In one embodiment of the present invention, the first purge gas is argon, which has a thermal conductivity that is 0.65 times that of nitrogen. Once the gas pressure in processing chamber is stabilized, the heating lamp assembly 16 is turned on at step 350 to heat up substrate 12 according to a heating schedule, such as the one shown in FIG. 3A.

At a predetermined point during the heating schedule, a second purge gas is introduced into reflective cavity 15 at step 360. The first purge gas flow into reflective cavity 15 may be terminated before or near the time when the second purge gas flow is started. In one embodiment of the present invention, the predetermined point is selected to be at or near the time when substrate 12 reaches the target peak temperature, such as within a second or so before or after substrate 12 reaches the target peak temperature, or within a second or so before or after the end of the soak time. The second purge gas is selected from a group of gases with relatively high thermal conductivity, such as helium, hydrogen, or a combination of these gases. In one embodiment of the present invention, the second purge gas is helium.

Because the gas pressure in processing chamber 14 is significantly lower than atmospheric pressure, the time it takes for the second purge gas to replace the first purge gas in reflective cavity 15 is also much shorter than in conventional annealing processes performed at a pressure level that is comparable to atmospheric pressure. For example, at 760 Torr, the time it takes for the second purge gas to replace the first purge gas is in the order of a few seconds, but at 10 Torr, this time is reduced to the order of milliseconds.

To further reduce the time for purge gas exchange, when the second purge gas is supplied into reflective cavity 15, the gas pressure in processing chamber 14 is adjusted at step 370 by adjusting the pressure set point in the pressure control system to a second pressure value. In one embodiment of the present invention, the second pressure value is about 1-500 Torr, and more typically about 10-100 Torr. The second pressure value is also about 5-10 times the first pressure value. The sudden pressure increase helps to achieve a much quicker increase in the mole fraction of the second purge gas in reflective cavity 15 after switching between the two different purge gases. Moreover, since thermal conductivity of a gas increases gradually with pressure in the above pressure range, the higher chamber pressure when the second purge gas is supplied further increases the conductivity of the purge gas between the substrate and the reflective plate assembly.

The rate at which the first purge gas is injected into reflective cavity 15 is not critical, as long as it is sufficiently high to achieve the purpose of entraining volatile contaminants and to assure a certain degree of temperature uniformity across the wafer. In one embodiment of the present invention, the first purge gas flow is in the range of about 0.1-5 standard liters per minute (slm), and more typically in the range of 1-3 slm. The rate at which the second purge gas is injected into or exhausted from reflective cavity 15 is relatively high during the time when the second purge gas is replacing the first purge gas. It has been found that when the rate at which the second purge gas is injected into the reflective cavity is approximately equal to the rate at which that gas is exhausted from the reflective cavity, the temperature uniformity across the substrate is optimized during the cool down phase. The rate at which the second purge gas is exhausted from the reflective cavity may also need to be optimized to achieve maximum temperature uniformity. For example, if the exhaust rate is too high, the second purge gas (e.g. helium) will flow out of the chamber too fast, causing cold spots to form on the substrate. On the other hand, if the exhaust rate is too low, the second purge gas flow will take too long to reach the entire region of the substrate, resulting in a temperature gradient across the substrate. In one embodiment of the present invention, the rate at which the second purge gas is injected into or exhausted from reflective cavity 15 is about 10-30 slm, and more typically about 20 slm, during a short period of time, such as a second or so, after the second purge gas flow is started. Afterwards, the rate at which the second purge gas is injected into reflective cavity 15 may be maintained at the same flow rate, or reduced to a lower flow rate, or the flow of the second purge gas may be stopped if purging in the reflective cavity is not desired.

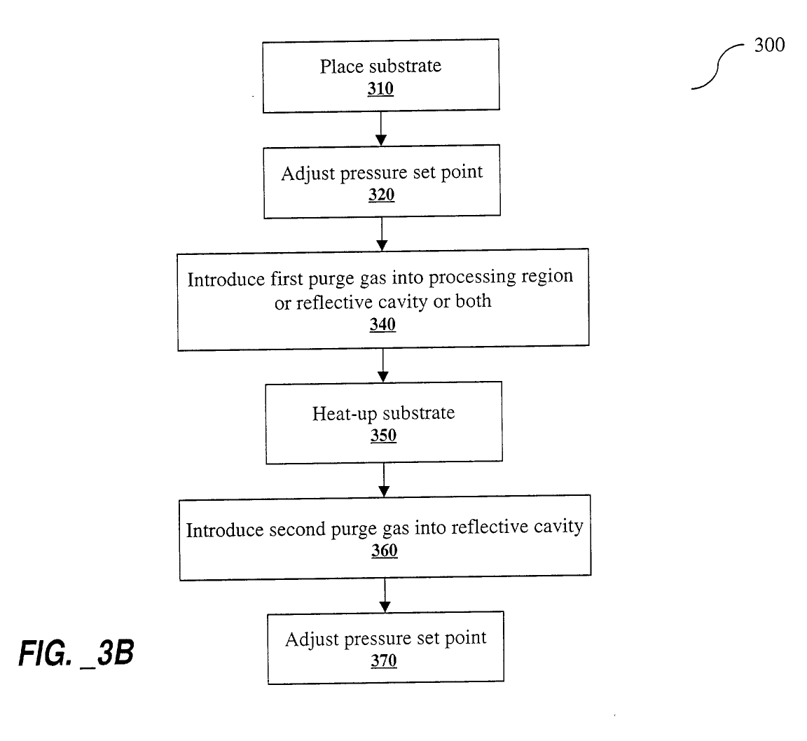

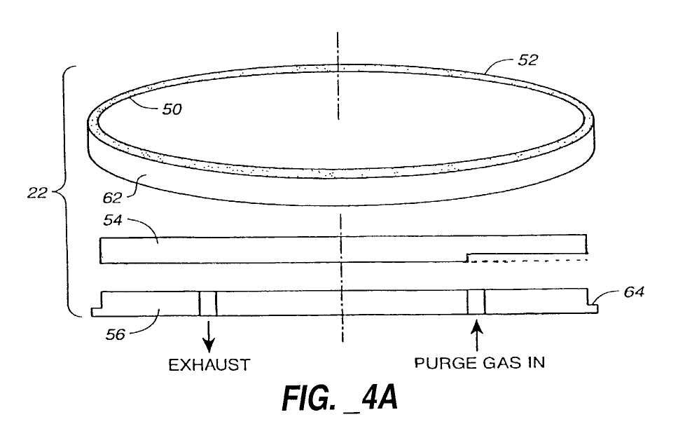

The temperature uniformity across substrate 12 during thermal processing may also be improved by optimizing the manner in which purge gases are introduced into reflective cavity 15. The purge gases may be supplied into reflective cavity 15 in a variety of different ways. Referring to FIGS. 4A and 4B, in one embodiment of a purge reflector 40, the reflector plate assembly 22 includes a deflector ring 52, a top reflector plate 54, and a bottom reflector plate 56. Bottom reflector plate 56 has a horizontal channel 58 for receiving purge gas from input 46 and for delivering the purge gas to a vertical channel 60, which communicates with a plurality of horizontal channels 48 in top reflector plate 54. Horizontal channels 48 distribute the purge gas to different locations at the periphery of top reflector plate 54. Deflector ring 52 includes a peripheral wall 62 which rests on a lower peripheral edge 64 of bottom reflector plate 56 and, together with the peripheral wall of top reflector plate 54, defines a 0.0275 inch wide vertical channel which directs the-purge gas flow against deflector 50 to produce a substantially laminar flow of purge gas across the top surface of reflector plate 54. The purge gas and any entrained volatile contaminants are removed from the processing chamber through exhaust port 44, or through ambient gas output 32. When exhaust port 44 is provided, a horizontal channel 66 in bottom reflector plate 56 receives the exhausted gas from exhaust port 44 and directs the exhausted gas to a line 68 that is connected to a pump system. Each of the channels 48, 58, and 60 may have a cross-sectional flow area of about 0.25 inch by about 0.1 inch.

Referring to FIG. 4C, a purge gas may be introduced into reflective cavity 15 at the top surface of top reflector plate 54 along a peripheral arc of about 75 degrees. The resulting substantially laminar flow of purge gas 42 extends over a region of the top surface of top reflector plate 54 corresponding to the 75-degree sector 70, which includes nine of the ten optical ports in top reflector plate 54 (including optical ports 25, 26, and 27).

Referring to FIG. 5, in another embodiment, a reflector plate assembly 100 is similar in construction to reflector plate assembly 22, except reflector plate assembly 100 is designed to introduce a purge gas 102 from different locations around the entire periphery of a top reflector plate 104. Purge gas 102 is removed through ambient gas output 32, or through an exhaust port 106 that extends through top reflector plate 104. Purge gas 102 may be introduced at locations about 4.33 inches from the center of reflector plate 104 for 200 mm substrates. When exhaust port 106 is provided, it may be located about 2 inches from the center of reflector plate 104. This embodiment may be used when optical ports 108 are distributed over the entire surface of reflector plate 104.

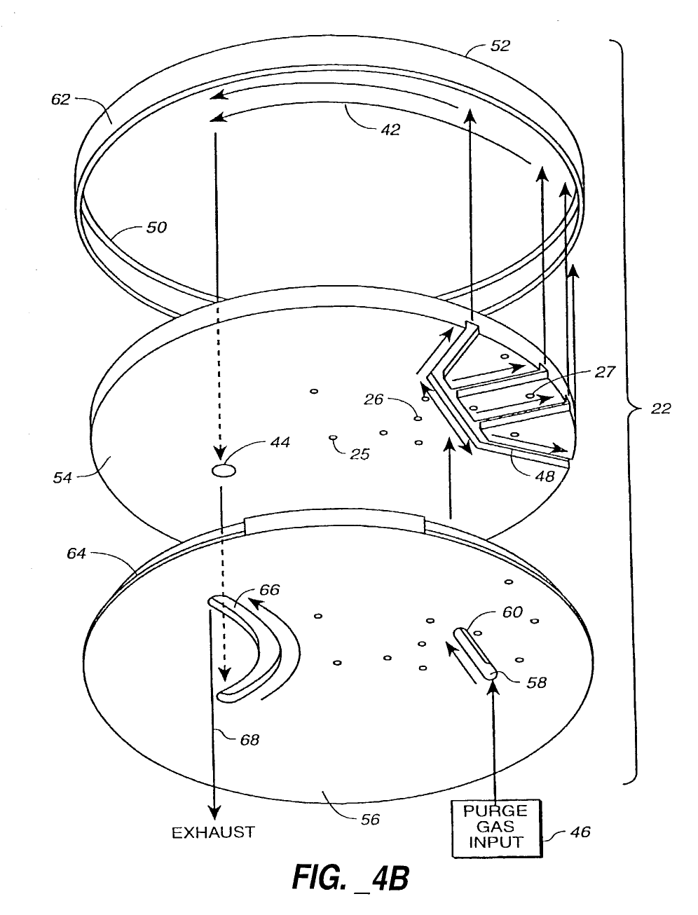

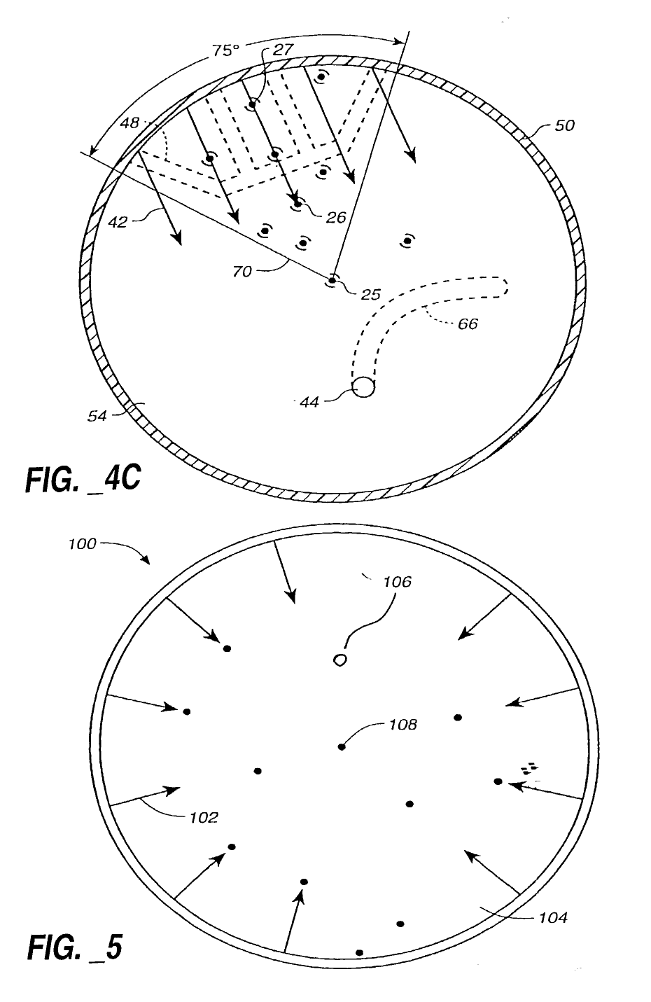

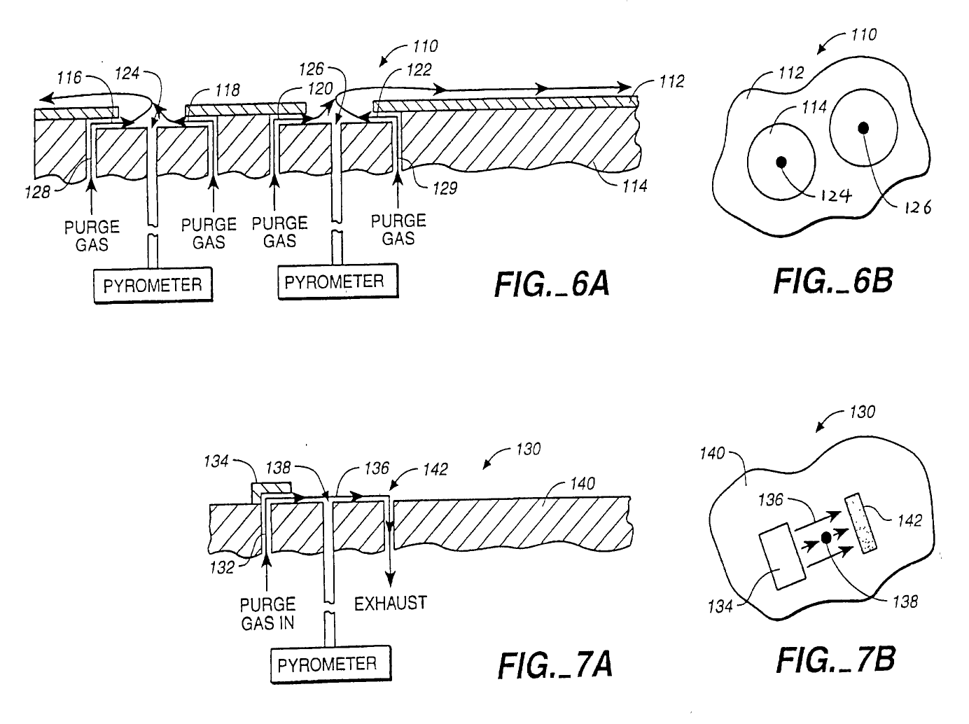

Referring to FIGS. 6A and 6B, in another embodiment, a reflector plate assembly 110 is also similar in construction to reflector plate assembly 22, except that reflector plate assembly 110 includes a deflector plate 112 and a reflector plate 114 that together define flow channels for producing a substantially laminar flow of purge gas in circumferential regions 116 and 122 surrounding optical ports 124 and 126, respectively. The purge gas flows through vertical annular channels 128, 129 in top reflector plate 114. The purge gas may be exhausted through ambient gas output 32, or through a separate exhaust port (not shown) that extends through top reflector plate 114; the purge gas may alternatively be exhausted over the circumferential edge of reflector plate assembly 110. In this embodiment, the top surface of deflector plate 112 acts as the primary optically reflective surface that faces the backside of the substrate. Deflector plate 112 may be spaced above top reflector plate 114 by a distance of 0.01 inch (0.25 mm).

Referring to FIGS. 7A and 7B, in another embodiment, a reflector plate assembly 130 includes a vertical channel 132 for receiving a flow of a purge gas, and a slot-shaped deflector 134 for deflecting the flow of purge gas 136 as a rectangular curtain across an optical port 138 that extends through a reflector plate 140. A slot-shaped exhaust port 142 is used to remove purge gas 136. Deflector 134 may be spaced above the top surface of reflector plate 140 by a distance of about 0.01 inch (0.25 mm).

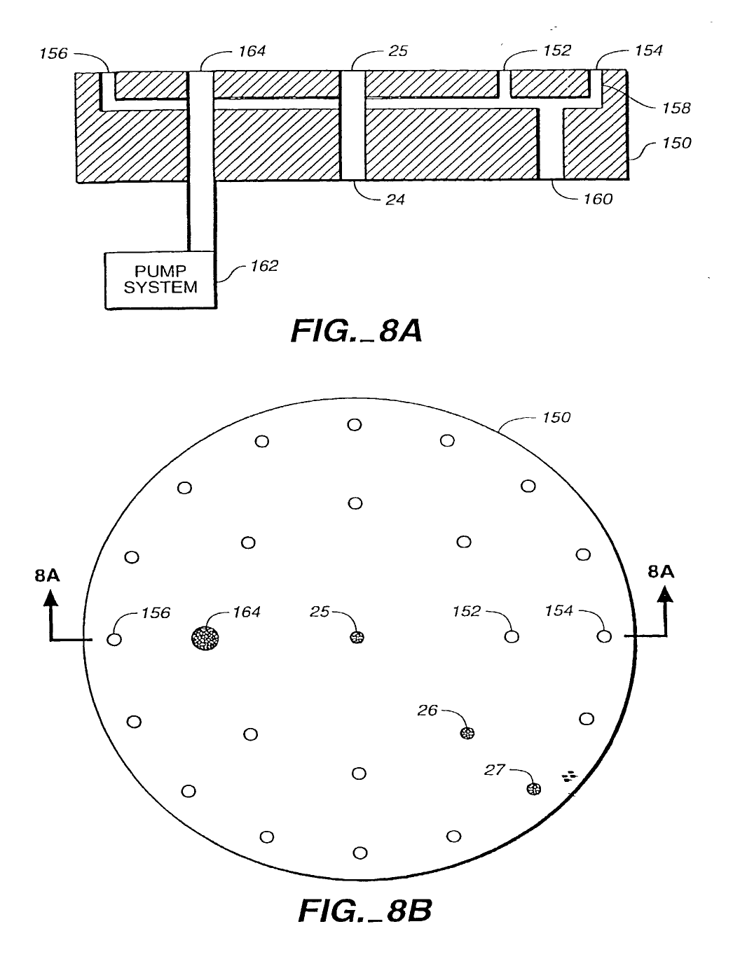

As shown in FIGS. 8A and 8B, in another embodiment, a reflector plate assembly 150 may include a plurality of orifices 152, 154, 156 which are coupled to a common gas plenum 158 which, in turn, is coupled to a purge gas input 160. Orifices 152-156 are arranged to uniformly introduce purge gas into the reflector cavity defined between substrate 12 and reflector plate assembly 150. Orifices 152-156 are also arranged to accommodate the locations of optical ports 25-27 through which temperature probes 24 receive light emitted by substrate 12. In operation, the purge gas flows into the reflector cavity at a flow rate of about 9-20 slm; in general, the flow rate should be less than the rate required to lift substrate 12 off support structure 20. Purge gas is removed from the reflector cavity by a pump system 162 through an exhaust port 164, or through ambient gas output 32.

Still other purge gas delivery systems are possible. For example, purge gas may be supplied by the rotating gas delivery system described in U.S. application Ser. No. 09/287,947, filed Apr. 7, 1999, and entitled “Apparatus and Methods for Thermally Processing a Substrate,” which is incorporated herein by reference.

The exact order of some of the steps in the process 300 and/or the operation of the processing chamber 14 as described above can be altered. In addition, steps may be added or omitted and process parameters varied depending upon the requirements of a particular processing application and the particular RTP system in which the annealing process takes place. The above operations and the order in which they are presented are chosen for illustrative purposes and to provide a picture of a complete run sequence.

What is claimed is:

1. A method of thermally processing a substrate in a processing chamber, comprising:
providing a flow of a first gas into the processing chamber;
while providing the flow of the first gas, maintaining gas pressure in the processing chamber near a first pressure level that is significantly lower than atmospheric pressure;
heating the substrate while providing the flow of the first gas; and
at or near the time the substrate temperature reaches a target peak temperature, providing a flow of a second gas into the processing chamber, the second gas being different from the first gas.

2. The method of claim 1, further comprising:
while providing the flow of the second gas, increasing gas pressure in the processing chamber such that the gas pressure in the processing chamber is near a second pressure level.

3. The method of claim 2 wherein the second pressure level is about 5-10 times higher than the first pressure level.

4. The method of clam 1 wherein the thermal conductivity of the second gas is greater than the thermal conductivity of the first gas.

5. The method of claim 1 wherein the flow of the second gas is provided between the substrate and a thermal reservoir.

6. The method of claim 5 wherein the thermal reservoir includes a relatively cool surface inside the processing chamber.

7. The method of clam 5 wherein the flow rate of the second gas is relatively high to quickly replace the first gas left between the substrate and a thermal reservoir.

8. The method of claim 1 wherein the substrate is processed according to a heating schedule comprising a heat-up phase and a cool-down phase, the flow of the first gas is provided during the heat-up phase of the heating schedule, and the flow of the second gas in provided during the cool-down phase of the heating schedule.

9. The method of claim 1 wherein the second gas is removed from the processing chamber at a rate which is substantially the same as the flow rate of the second gas into the processing chamber.

10. The method of claim 1 wherein the flow of the first gas is terminated before or near the time when the flow of the second gas is started.

11. The method of claim 1 wherein the first gas includes argon, krypton, xenon, nitrogen, or combinations thereof.

12. The method of claim 1 wherein the second gas includes helium, hydrogen, or both.

13. The method of claim 1 wherein the first pressure level is in the range of 1-20 Torr.

14. A method of thermally processing a substrate in a processing chamber, comprising:
heating the substrate while maintaining the gas pressure in the processing chamber near a first pressure level that is substantially lower than atmospheric pressure; and
at or near a time the substrate temperature reaches a target peak temperature, providing a flow of a gas between the substrate and a thermal reservoir in the processing chamber, the gas enhancing thermal transfer between the substrate and the thermal reservoir in the processing chamber.

15. The method of claim 14, further comprising:
increasing gas pressure in the processing chamber such that the gas pressure in the processing chamber is near a second pressure level.

16. The method of claim 15 wherein the second pressure level is about 5-10 times higher than the first pressure level.

17. The method of claim 14 wherein the thermal reservoir includes a relatively cool surface inside the processing chamber.

18. The method of claim 14 wherein the substrate is processed according to a heating schedule comprising a heat-up phase and a cool-down phase, and the flow of the gas in provided during the cool-down phase of the heating schedule.

19. The method of clam 14 wherein a flow rate of the gas is relatively high to minimize the time the substrate spends near the target temperature.

20. The method of claim 14, further comprising
removing the gas from the processing chamber at a rate which is substantially the same as the flow rate of the gas into the processing chamber.

21. The method of claim 14 wherein the gas has a relatively high thermal conductivity.

22. The method of claim 14 wherein the first pressure level is in the range of 1-20 Torr.
